(19) United States
(12) Patent Application Publication
(10) Pub. No.: US 2007/0246729 A1
(43) Pub. Date: Oct. 25, 2007

(54) High efficiency LED package

(76) Inventor: Ik-Seong Park, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/788,132

(22) Filed: Apr. 18, 2007

(30) Foreign Application Priority Data
Apr. 20, 2006 (KR) 10-2006-0035782

(51) Int. Cl. H01L 33/00

(52) U.S. Cl. 257/99

(57) ABSTRACT

A light emitting diode (LED) package is disclosed. In one embodiment, the LED package includes an LED, which emits light corresponding to an electric signal and a substrate, which is mounted to electrically couple to the LED and has an anode lead frame and a cathode lead frame. The package also includes a voltage regulator diode, which is mounted on the substrate and has a parallel connection with the LED to maintain voltage regulation. The LED package further includes a shielding dam, which is located between the LED and the voltage regulator diode and prevents light emitted by the LED from being directly irradiated to and reflected or absorbed by the voltage regulator diode. In at least one embodiment, the LED package can prevent the light emitted by the LED from being directly absorbed by the voltage regulator diode.

### BACKGROUND OF THE INVENTION

1. Field of the Invention

The present invention is directed to a light emitting diode (LED) package, more specifically to an LED package with a high reflectivity.

2. Description of the Related Technology

Generally, an LED refers to an electronic device that makes injected minority carriers (electrons or positive holes) using the p-n junction of a semiconductor and emits light by the re-bonding of these. When a forward direction (or positive) voltage is applied to a semiconductor of a particular element, the electrons and positive holes move through the junction of an anode and a cathode and become re-bonded. Since the energy becomes smaller than when the electrons and positive holes are separated, light is emitted due to the difference of energy.

LEDs are often used in home appliances, remote controls, electronic billboards, displays, and automation equipment. With telecommunications devices getting increasingly smaller and slimmer, the resistance, condenser, and noise filter are becoming much smaller, and LEDs have become a surface mount device (SMD) type in order for it to be directly mounted on the printed circuit boards.

The SMD type of LED package, which is mainly used for a backlight unit of an LCD in mobile phones, is generally known to be vulnerable to static electricity or reverse voltage. It has been attempted to supplement this vulnerability by providing means for allowing the electric current in the reverse direction, preferably by making a parallel connection between a Zener diode and a light-emitting chip. That is, the light-emitting diode and Zener diode are mounted on the anode and cathode, and the light-emitting diode and Zener diode are connected parallel by a gold (Au) wire.

### SUMMARY OF CERTAIN INVENTIVE ASPECTS

One aspect of the present invention provides a high efficiency LED package that prevents the light emitted by an LED from being absorbed by a voltage regulator diode.

Another aspect of the present invention provides a high efficiency LED package using a voltage regulator diode without any restriction of usage and use.

Another aspect of the present invention provides a high efficiency LED package that can reflect the light that would be otherwise absorbed by the voltage regulator diode.

Another aspect of the present invention provides a high efficiency LED package that can emit highly luminous light by adjusting an angle of a reflecting part in the LED package.

Another aspect of the present invention provides an LED package, which includes i) an LED, which emits light corresponding to an electric signal, ii) a substrate, which is mounted to electrically couple to the LED and has an anode lead frame and a cathode lead frame, iii) a voltage regulator diode, which is mounted on the substrate and has a parallel connection with the LED to maintain voltage regulation, and iv) a shielding dam, which is located between the LED and the voltage regulator diode and prevents light emitted by the LED from being directly irradiated to and reflected or absorbed by the voltage regulator diode.

The LED package can be a side view LED. The voltage regulator diode can be a Zener diode or an avalanche diode. The shielding dam can be made of one of aluminum, silver and plastic. The cross section of the shielding dam can be a rectangle or a triangle. The side of the shielding dam facing the LED can be coated with a reflective material. The reflective material can be one of aluminum, silver, and plastic.

The side of the shielding dam facing the LED can be tilted at an angle from the substrate. The LED package can also have a reflecting part, which is formed on the substrate, surrounds the LED, the voltage regulator diode, and the shielding dam, and reflects light emitted by the LED to the outside.

The reflecting side formed on a side of the reflecting part can form an angle from the substrate in accordance with an angle of a side of the shielding dam. The shielding dam can be made of the same material of the reflecting part. The shielding dam can be made of poly parabanic acid resin or nylon.

### BRIEF DESCRIPTION OF THE DRAWINGS

Embodiments of the present invention will be described in connection with accompanying drawings.

FIG. 1 shows a sectional view of a typical LED package using a voltage regulator diode.

FIG. 2 shows a perspective view of a high efficiency LED package in accordance with a first embodiment of the present invention.

FIG. 3 shows a sectional view of the high efficiency LED package in accordance with the first embodiment of the present invention.

FIG. 4 shows a plan view of the high efficiency LED package in accordance with the first embodiment of the present invention.

FIG. 5 is a side sectional view of the high efficiency LED package in accordance with the first embodiment of the present invention.

FIG. 6 shows a circuit schematic of the high efficiency LED package in accordance with the first embodiment of the present invention.

FIG. 7 shows a sectional view of a high efficiency LED package in accordance with a second embodiment of the present invention.

FIG. 8 shows a sectional view of a high efficiency LED package in accordance with a third embodiment of the present invention.

### DETAILED DESCRIPTION OF CERTAIN INVENTIVE EMBODIMENTS

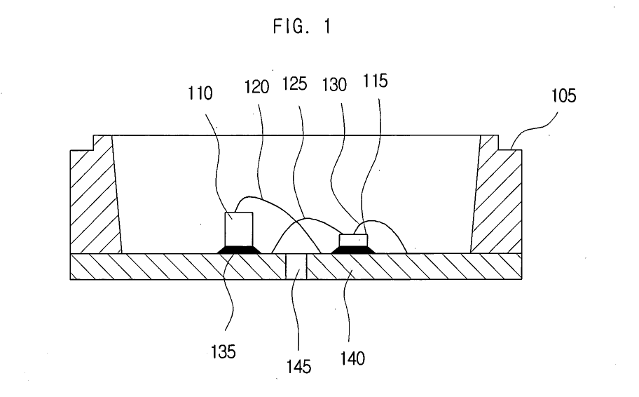

FIG. 1 is a sectional view of a typical LED package using a voltage regulator diode. The LED package may include a reflecting unit 105, a Zener diode 110, an LED 115, wires 120, 125, and 130, and a substrate. The substrate may include an anode lead frame 135, a cathode lead frame 140, and an insulation area 145.

By making a parallel connection of the Zener diode 110 and the LED 115, the Zener diode can prevent damage caused by static electricity when the current is applied in the reverse direction. The Zener diode is also called a “voltage regulator diode,” which is one of the semiconductor PN junction diodes. Designed to show operation properties in a breakdown area of PN junction, the Zener diode is mostly used for voltage regulation. The Zener diode obtains a certain voltage by use of the Zener recovery phenomenon. It operates in about 10 mA of current in the p-n junction of silicon, and can achieve about 3V to about 12V of voltage regulation, depending on the type. The Zener diode 110 can be mounted directly on the substrate or by use of the lead frame as shown in FIG. 1.

The Zener diode 110, however, has a problem of absorbing the light emitted by the LED 115, since it is located near the LED 115. In other words, the light-emitting efficiency of the LED package becomes lower as the Zener diode 110 absorbs some of the light of the LED 115 that is directed to the Zener diode 110.

In one embodiment of the present invention, a shielding dam is formed between the LED and the voltage regulator diode to prevent the light emitted by the LED being absorbed by the voltage regulator diode. The shielding dam can be shaped to have a certain angle to reflect the light emitted by the LED to the outside, and can be made of a reflective material or formed with a reflective side to increase reflectivity. Moreover, the LED package can have a reflecting part to increase the luminosity of the light emitted by the LED. The reflecting part can be formed in accordance with the angle of the shielding dam, that is, the section can have a tapered shape.

Certain embodiments of a high efficiency LED will be described with reference to the accompanying drawings. In the drawings, identical elements will be given the same reference numeral regardless of the figure number, and any redundant description regarding the same element will not be provided. Mainly, three embodiments are described here, based on the shape of the shielding dam formed between the LED and the voltage regulator diode. Although the side view type of LED package will be described, at least one embodiment of the present invention can be also applied to other LED packages, such as a top view type, a type used in a flash light, a power LED used in a light. Moreover, although the Zener diode is used to describe the voltage regulator diode, it shall be evident that any device (e.g. an avalanche diode) having an effect of voltage regulation can be applied in embodiments of the present invention.

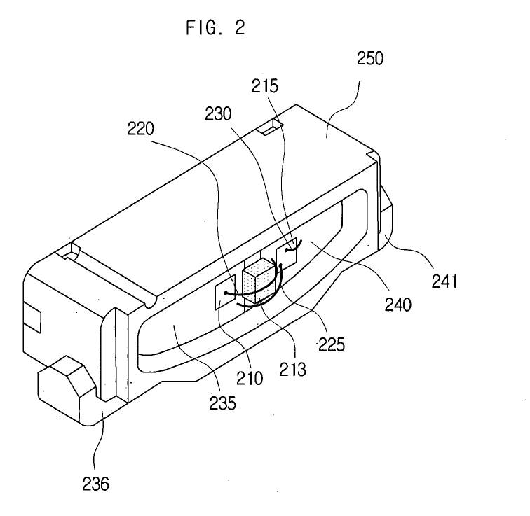

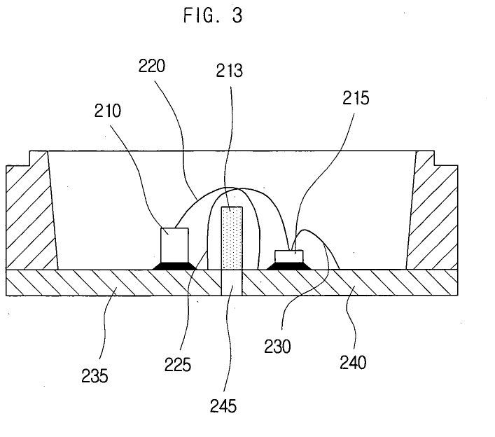

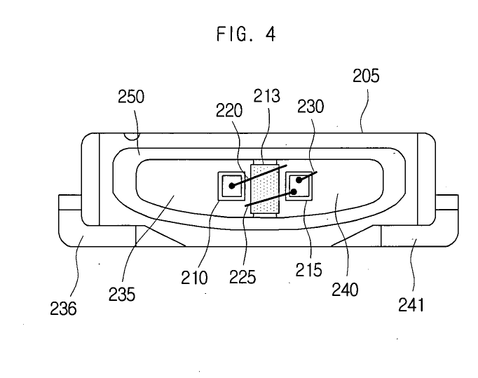

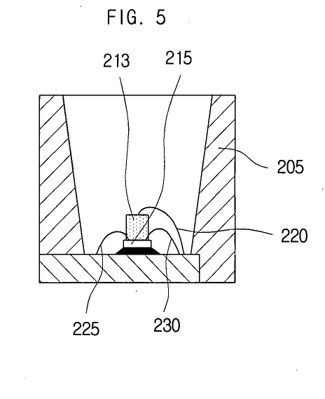

FIG. 2 is a perspective view of a high efficiency LED package in accordance with a first embodiment of the present invention, and FIGS. 3, 4, and 5 are a sectional view seen from the front, a plan view seen from the top, and a sectional view seen from the side of the high efficiency LED package shown in FIG. 2. As shown in FIGS. 2 to 5, the high efficiency LED package may include a projectile body 205, a voltage regulator diode 210, a shielding dam 213, an LED 215, a first wire 220, a second wire 225, a third wire 230, a reflecting part 250, and a substrate. The substrate may include anode lead frames 235 and 236, cathode lead frames 240 and 241, and an insulation area 245.

For the LED 215, a typical LED can be used, for example, from the GaN group. A GaN line of light-emitting chip is designed to irradiate a wavelength band of blue color when emitting light. By applying a fluorescent material producing the light of yellow wavelength band on top of the light-emitting chip, the white light can be made. Here, it is also possible to make the white light by using red, green, and blue fluorescent materials.

The LED package may include i) the LED 215, which is disposed inside the projectile body 205 and irradiates light when electricity is applied, ii) a voltage regulator diode 210, which is for preventing damage caused by static electricity by making a parallel connection with the LED 215, and iii) a reflecting part 250, which reflects the light emitted by the LED 215 to the outside. The projectile body 205 can be made of plastic, especially of poly parabanic acid resin (referred to as “PPA” hereinafter), which has a high mechanical strength and a high reflectivity. The reflecting part 245 is formed on the substrate, surrounding the LED 215, the voltage regulator diode 210, and the shielding dam 213, and can be formed in one body with the projectile body 205 or separately from the projectile body 205. On one side of the projectile body are the anode lead frames 235 and 236 and the cathode lead frames 240 and 241, each of which are protruded. The anode lead frames 235 and 236 and the cathode lead frames 240 and 241 are electrically connected. The voltage regulator diode 210, the shielding dam 213, the LED 215, the first wire 220, the second wire 225, and the third wire 230 are protected by resin, for example, epoxy resin.

The anode lead frame 235 is mounted with the voltage regulator diode 210, and the cathode lead frame 240 with the LED 215. The voltage regulator diode 210 and/or the LED 215 can be mounted by the die bonding method with a conductive epoxy.

The LED can be electrically connected to the anode lead frame 235 through the second wire 225. Therefore, the light can be irradiated from the LED 215 by applying the forward-direction current applied to the cathode lead frame 235 to the LED 215. The highly conductive gold (Au) can be used for the second wire 225.

The voltage regulator diode 210 has a physical property of electrostatic resist pressure against reverse-direction currents. Thus, if reverse-direction currents are applied to the LED 215 by, for example, static electricity, the currents are bypassed by the voltage regulator diode 210, preventing damage by the static electricity. Although the voltage regulator diode 210 includes a Zener diode, any device, such as an avalanche diode, a switching diode, and a schottky diode, having the effect of regulating the voltage can be included.

The voltage regulator diode 210 may include the first wire 220, which is extended from the voltage regulator diode 210 and wire-bonded to the cathode lead frame 240. Here, the first wire 220 can be connected to the third wire 230, which is extended form the LED 215, making a parallel connection of the voltage regulator diode 210 to the LED 210.

The shielding dam 213 may be located between the voltage regulator diode 210 and the LED 215, and can substantially prevent the light emitted from the LED 215 from directly irradiating on the voltage regulator diode 210 and being reflected directly to or absorbed by the voltage regulator diode 210. Thus, the shielding dam 210 can be made of a reflective material, or the side of the exterior including the side facing the LED 210 can be coated with a reflective material, such that the light emitted by the LED 215 can be efficiently emitted to the outside.

The reflective material forming or coated on the shielding dam 213 can be aluminum (Al) or silver (Ag), which are highly reflective, or can be the highly reflective PPA, which is used to form the projectile body 205, or the highly reflective nylon. If the shielding dam 213 is made of the same material as the material forming the projectile body 205, the shielding dam 213 and the projectile body 205 can be formed by the same process, simplifying the manufacturing process.

A typical LED package having both the voltages regulator diode 210 and the LED 215 generates the light of 1 cd if the LED of 1 cd is used. With the shielding dam 210, however, the light of about 1.1 cd can be generated. To increase the reflection efficiency, the reflecting part 245 of the shielding dam 213 can be formed at an angle from the substrate.

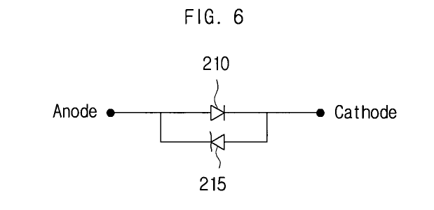

FIG. 6 is a circuit schematic of a high efficiency LED package in accordance with a first embodiment of the present invention. Referring to FIG. 6, the voltage regulator diode 210 and the LED 215 have a parallel connection to the anode lead frame 235 and the cathode lead frame 240.

When the forward-direction current is applied to the LED package, the current is supplied to the LED 215 via the anode lead frame 235 and the first wire 220, making the LED 215 irradiate the light having R, G, and B colors. Since the Zener diode is in the reverse direction, it is electrically open, and thus protects the LED 215 by being short when it is over a certain voltage. Therefore, the LED 215 can have a stable irradiation of light by maintaining the supply of current with the forward-direction voltage (anode to cathode) within a certain range to the LED 215.

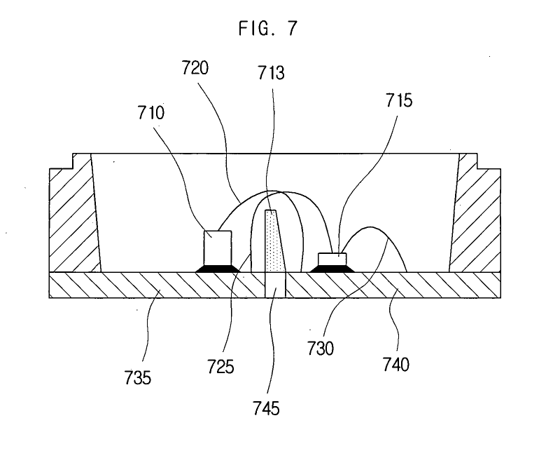

If a reverse-direction voltage is applied due to, for example, static electricity, the reverse-direction voltage is supplied to the voltage regulator diode 210, which is electrically a forward direction. The LED 215 is electrically open. Here, if the voltage is applied in the reverse direction, the voltage regulator diode 210 bypasses the current by being short, preventing the LED 215 from being damaged. Therefore, by making a parallel arrangement of the voltage regulator diode 210 with the LED 215, the damage to the LED by the forward-direction and reverse-direction currents can be prevented. FIG. 7 is a sectional view of a high efficiency LED package in accordance with a second embodiment of the present invention. Referring to FIG. 7, the LED package has a voltage regulator diode 710, a shielding dam 713, an LED 715, a first wire 720, a second wire 725, a third wire 730, and a substrate. The substrate may include an anode lead frame 735, a cathode lead frame 740, and an insulation area 745.

The shielding dam 713 is tilted to an angle such that the light emitted by the LED 715 can be efficiently irradiated to the outside. That is, the side on which the shielding dam 713 faces the LED 715 can be tilted at an angle to the substrate (i.e. the anode lead frame 735, the cathode lead frame 740, and the insulation area 745). The tilted side can be a portion of the side or the entire side. The tilt can be formed at an angle by which the reflection efficiency of the light is good. Therefore, the section of the shielding dam 713 can be a shape of a polygon, for example, a rectangle or a triangle.

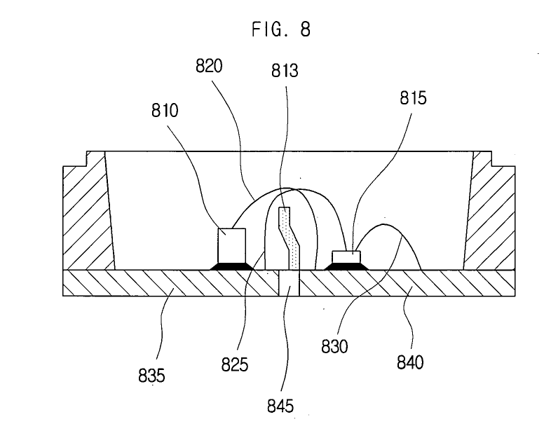

FIG. 8 is a sectional view of a high efficiency LED package in accordance with a third embodiment of the present invention. Referring to FIG. 8, the LED package may include a voltage regulator diode 810, a shielding dam 813, an LED 815, a first wire 820, a second wire 825, a third wire 830, and a substrate. The substrate may include an anode lead frame 835, a cathode lead frame 840, and an insulation area 845.

The shielding dam 813 can have a shape of a plate which is bent in the middle. That is, to irradiate the light emitted by the LED 815 to the outside efficiently, the shielding dam 813 is shaped as if a plate is bent, requiring less material to form the shielding dam 813. It is evident that any other shape that can efficiently reflect the light emitted by the LED 815 can be applied to the present invention. For example, the entire shielding dam can be slanted to one side, as in a “\” shape.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A light emitting diode (LED) package comprising:
a substrate including i) an anode lead frame, ii) a cathode lead frame and iii) an insulator located between the anode and cathode lead frames and configured to electrically insulate the two frames;
an LED located on one of the anode and cathode lead frames and configured to emit light corresponding to an electric signal;
a voltage regulator diode located on the other lead frame of the substrate, wherein the voltage regulator diode is configured to regulate a voltage of the LED at a predetermined level; and
a shielding dam located on the insulator of the substrate and configured to substantially prevent light emitted by the LED from being directly irradiated to and reflected or absorbed by the voltage regulator diode.

2. The LED package of claim 1, wherein the LED package comprises a side view LED.

3. The LED package of claim 1, wherein the voltage regulator diode comprises a Zener diode or an avalanche diode.

4. The LED package of claim 1, wherein the shielding dam is made of one of aluminum, silver and plastic.

5. The LED package of claim 1, wherein the cross section of the shielding dam is a rectangle or a triangle.

6. The LED package of claim 1, wherein a side of the shielding dam facing the LED is coated with a reflective material.

7. The LED package of claim 6, wherein the reflective material comprises one of aluminum, silver, and plastic.

8. The LED package of claim 1, wherein a side of the shielding dam facing the LED is tilted at an angle from the substrate.

9. The LED package of claim 1, further comprising a reflecting portion formed on the substrate, wherein the reflecting portion surrounds the LED, the voltage regulator diode, and the shielding dam, and wherein the reflecting portion is configured to reflect light emitted by the LED to environment.

10. The LED package of claim 9, wherein a reflecting side formed on a side of the reflecting portion forms an angle from the substrate in accordance with an angle of a side of the shielding dam.

11. The LED package of claim 9, wherein the shielding dam is made of the same material as that of the reflecting portion.

12. The LED package of claim 11, wherein the shielding dam is made of poly parabanic acid resin or nylon.

13. A light emitting diode (LED) package comprising:
an LED configured to emit light;
a voltage regulator configured to regulate a voltage of the LED at a predetermined level; and
a plate located between the LED and the voltage regulator and configured to substantially prevent light emitted by the LED from entering the voltage regulator.

14. The LED package of claim 13, further comprising a substrate which includes i) an anode lead frame, ii) a cathode lead frame and iii) an insulator located between the anode and cathode lead frames and configured to electrically insulate the two frames.

15. The LED package of claim 14, wherein the plate is located on the insulator.

16. The LED package of claim 14, wherein the plate is greater in height than the LED and voltage regulator from the substrate.

17. The LED package of claim 14, wherein the voltage regulator is electrically connected to the cathode lead frame via a first wire, and wherein the plate is located underneath the first wire.

18. The LED package of claim 14, wherein the LED is electrically connected to the anode frame via a second wire, and wherein the plate is located underneath the second wire.

19. The LED package of claim 13, wherein at least a portion of the plate is slanted toward the voltage regulator.

20. The LED package of claim 13, wherein the voltage regulator comprises a voltage regulator diode.

21. A light emitting diode (LED) package comprising:
a substrate including first and second portions which are electrically insulated from each other;
an LED located on the first portion and configured to emit light;
a voltage regulator diode located on the second portion and configured to regulate a voltage of the LED at a predetermined level; and
means for substantially preventing light emitted by the LED from entering the voltage regulator diode.
